(19) United States
(12) Patent Application Publication
(10) Pub. No.: US 2022/0146710 A1
(43) Pub. Date: May 12, 2022

(54) OPTICAL METASURFACES, AND ASSOCIATED MANUFACTURING METHODS AND SYSTEMS

(71) Applicants: Université D'Aix-Marseille, Marseille (FR); Centre National de la Recherche Scientifique, Paris (FR); Ecole Centrale de Marseille, Marseille (FR); Multiwave Innovation, Marseille (FR)

(72) Inventors: Elena Mikheeva, Marseille (FR); Redha Abdeddaim, Marseille (FR); Stefan Enoch, Marseille (FR); Julien Lumeau, Marseille (FR); Ivan Voznyuk, Marseille (FR); Tryfon Antonakakis, Geneva (CH)

(73) Assignees: Université D'Aix-Marseille, Marseille (FR); Centre National de la Recherche Scientifique, Paris (FR); Ecole Centrale de Marseille, Marseille (FR); Multiwave Innovation, Marseille (FR)

(21) Appl. No.: 17/430,961

(22) PCT Filed: Feb. 14, 2020
(86) PCT No.: PCT/EP2020/053988

§ 371 Date: Aug. 13, 2021

(30) Foreign Application Priority Data
Feb. 15, 2019 (FR) 1901570

(51) Int. Cl. G02B 1/00; G02B 1/12; C03C 23/00; G03F 7/00

(52) U.S. Cl. CPC G02B 1/002; G02B 1/12; G02B 2207/101; G03F 7/0005; C03C 23/0025

(57) ABSTRACT

A method for manufacturing an optical metasurface is configured to operate in a given working spectral band. The method comprises: obtaining a 2D array of patterns, each comprising one or more nanostructures forming dielectric elements that are resonant in said working spectral band, said nanostructures being formed in at least one photosensitive dielectric medium; exposing said 2D array to a writing electromagnetic wave having at least one wavelength in said photosensitivity spectral band, said writing wave having a spatial energy distribution in a plane of the 2D array that is a function of an intended phase profile, so that each pattern of the 2D array produces on an incident electromagnetic wave having a wavelength in the working spectral band, a phase variation corresponding to a refractive index variation experienced by said pattern during said exposure.

### TECHNICAL FIELD OF THE INVENTION

The present invention relates to the field of optical metasurfaces, and more particularly to the custom manufacturing of dielectric optical metasurfaces.

### BACKGROUND

For the control of light beams, and more generally for controlling electromagnetic waves, the traditional components, for example prisms or lenses, generate cumulative phase retardations during propagation through the material from which they are formed. Thus, for a prism or a lens, for example, the thickness traveled through in the material with a given refractive index varies continuously in order to increase the optical path compared to propagation in air. The optical function of a component is therefore entirely determined by its intrinsic properties, such as for example the shape and the refractive index.

Currently, nanotechnologies are making it possible to design a new class of optical components, referred to as “optical metasurfaces”, formed by 2D optical elements comprising nanostructures, for example nanopillars or other particles made of dielectric or metallic material, forming gratings of resonant or quasi-resonant elements. The optical metasurfaces, which are described, for example, in the review article by Minovich et al., “Functional and nonlinear optical metasurfaces”, Laser Photonics Rev., 1-19 (2015), allow in particular abrupt changes of phase, amplitude and/or polarization over a thickness scale of the order of the wavelength. In comparison with traditional optical components, they thus offer great flexibility in controlling the wavefront, in addition to being planar components with a thickness that is very small, that is to say less than or equal to the wavelength. Controlling the propagation of light in optical metasurfaces requires structuring on the sub-wavelength scale in two of the three dimensions of space, making the technological challenge particularly difficult.

For example, the published patent application US 2017/0212285 describes dielectric optical metasurfaces that have resonant elements distributed in a 2D array and make it possible to control the phase of incident waves in the infrared range. The resonant elements are structurally different and distributed in such a way as to generate the desired phase profile. For example, the resonant elements have different lateral dimensions in order to generate the desired phase profile.

In order to produce local control of the phase in the optical metasurfaces such as are described in the aforementioned document, it is thus necessary to control each resonant element of the metasurface perfectly on the wavelength scale. This constraint makes the method difficult to carry out on a large scale. Therefore, these technologies are often restricted to laboratory demonstrators.

It is an object of the present description to provide a new method for manufacturing an optical metasurface, which makes it possible to overcome at least some of the difficulties of the prior art.

### SUMMARY OF THE INVENTION

According to a first aspect, the present description relates to a method for manufacturing an optical metasurface configured to operate in a given working spectral band, the method comprising the following steps:
obtaining a 2D array of patterns, each comprising one or more nanostructures forming dielectric elements that are resonant in said working spectral band, said nanostructures being formed in at least one photosensitive dielectric material, said at least one photosensitive dielectric material having a refractive index that can be varied by exposure to at least one writing electromagnetic wave having a wavelength lying in a photosensitivity spectral band;
exposing said 2D array to a writing electromagnetic wave having at least one wavelength in said photosensitivity spectral band, said writing wave having a spatial energy distribution in a plane of the 2D array that is a function of an intended phase profile, so that each pattern of the 2D array produces, following said exposure, on an incident electromagnetic wave having a wavelength in the working spectral band, a phase variation corresponding to a refractive index variation experienced by said pattern during said exposure.

The manufacturing method thus described allows custom manufacturing of an optical metasurface, the local control of the refractive index being carried out a posteriori, that is to say after obtaining the 2D array of patterns comprising resonant dielectric elements, as a function of the optical function intended for the optical metasurface. It is thus possible to produce optical metasurfaces with large dimensions, that is to say more than a few mm².

According to one or more exemplary embodiments, said patterns comprising one or more resonant dielectric elements are identical and arranged periodically along two directions, with a sub-wavelength period along each direction. It is thus possible to manufacture a uniform 2D array first, and to control in a customized way the phase profile that is intended to be generated by means of local variations of the refractive index.

An optical metasurface is an optical component nanostructured on the sub-wavelength scale in two of the three dimensions of space, in which the nanostructures, for example nanopillars or other particles made of dielectric or metallic material, form gratings of resonant or quasi-resonant elements.

The term “identical patterns” is intended to mean patterns that are identical before the exposure, that is to say patterns of resonant dielectric elements which comprise the same arrangement of resonant dielectric elements, with the same shapes and the same dimensions for the resonant dielectric elements from one pattern to another.

In other exemplary embodiments, using the manufacturing method according to the present description it is also possible to apply local refractive index variations to a 2D array that is not necessarily uniform, for example in order to correct an initial phase profile.

The term sub-wavelength is generally intended, unless otherwise indicated, to mean a period less than the minimum length of the working spectral band.

In the present description, the term “dielectric material” refers to a material that has a refractive index with a dominant real part, in contrast to a metal, in which the imaginary part of the refractive index dominates. Thus, except for photon energies greater than the bandgap width, semiconductors are low-loss dielectric materials.

In the present description, the term “photosensitive dielectric material” refers to a dielectric material which has a refractive index that can be varied by exposure to at least one writing electromagnetic wave. The photosensitivity spectral band comprises all the wavelengths for which the refractive index is variable.

According to one or more exemplary embodiments, the refractive index may vary by values of up to 2%, advantageously 3%, in the photosensitivity spectral band.

According to one or more exemplary embodiments, the obtaining of the 2D array comprises depositing said at least one photosensitive dielectric material on a substrate and forming said nanostructures in said at least one photosensitive dielectric material.

According to one or more exemplary embodiments, the obtaining of the 2D array comprises depositing on a substrate a layer or a stack of layers of a dielectric material, which is deposited on said substrate, the layer or said stack of layers comprising said at least one photosensitive dielectric material.

According to one or more exemplary embodiments, the obtaining of the 2D array comprises selectively depositing the photosensitive dielectric material on a substrate, for example by means of a mask, in order to form the resonant dielectric elements.

According to one or more exemplary embodiments, said stack of layers comprises at least one layer formed by said at least one photosensitive dielectric material and one or more additional layers, for example an antireflection layer and/or a connecting layer between the substrate and said at least one layer formed by said at least one photosensitive dielectric material. According to one or more exemplary embodiments, said stack of layers comprises at least one second layer formed by a second photosensitive dielectric material.

According to one or more exemplary embodiments, the obtaining of the 2D array comprises depositing said at least one photosensitive dielectric material on a substrate.

According to one or more exemplary embodiments, the substrate comprises a material that is transparent in the working spectral band. Thus, for example, the substrate may comprise at least one of the following materials: silica, glass, chalcogenide glass, ZnSe (zinc selenide), polymer.

A material is referred to as being transparent in a spectral band in the sense of the present description if, for each wavelength of said spectral band, at least 50%, preferably at least 80% and more preferably at least 90%, of a wave at said wavelength is transmitted.

According to one or more exemplary embodiments, the obtaining of the 2D array comprises forming said nanostructures directly in a substrate comprising said at least one photosensitive dielectric material.

According to one or more exemplary embodiments, the substrate comprises one or more additional layers, for example an antireflection layer.

According to one or more exemplary embodiments, the working spectral band lies in the transparency spectral band of said at least one photosensitive dielectric material, that is to say the spectral band comprising the wavelengths longer than a wavelength corresponding to the energy of the bandgap (or optical gap).

In practice, the working spectral band lies around the resonance spectral band of the resonant dielectric elements but is not limited to said resonance spectral band.

According to one or more exemplary embodiments, the working spectral band has a width of between 1 nm and 20 nm, or 1 nm to 100 nm. Depending on the materials used and the resonant dielectric elements, it may lie in the visible spectral band, the near infrared or the mid-infrared, for example between 400 nm and 15 μm.

According to one or more exemplary embodiments, the photosensitivity spectral band lies in the linear absorption spectral band of said at least one photosensitive dielectric material, that is to say the wavelengths shorter than the wavelength corresponding to the bandgap energy. This is referred to as linear photosensitivity.

In a dielectric material with linear photosensitivity, the variation of the refractive index depends on the amount of energy absorbed by the material. It is then possible to use any light source for emitting the writing electromagnetic wave, an increase in the power by a factor N making it possible to reduce the exposure time of the 2D array with a duration N times less. For example, the emission source comprises light-emitting diodes, laser diodes, continuous or pulse lasers, a xenon lamp.

According to one or more exemplary embodiments, the linear photosensitivity spectral band lies between 300 nm and 1000 nm.

Examples of dielectric materials with linear photosensitivity comprise, for example and without limitation, chalcogenide glasses (e.g. Ge₂₅As₃₀S₄₅, Ge₃₃As₁₂Se₅₅, As₂S₃, etc.). Oxide glasses may also be mentioned, for example photo-thermo-refractive materials described in J. Lumeau et al. [Ref.3], for example Foturan® or photosensitive polymer materials, for example PQ:PMMA described in G. J. Steckman et al., “Characterization of phenanthrenequinone-doped poly(methyl methacrylate) for holographic memory,” Opt. Lett. 23(16), 1310-1312 (1998).

According to one or more exemplary embodiments, the photosensitivity spectral band lies in a spectral band of nonlinear absorption of said at least one photosensitive dielectric material, for example a two-photon or multiphoton absorption. This is referred to as nonlinear photosensitivity.

During a nonlinear absorption mechanism, a high power density (in general obtained with the aid of a pulsed laser) is used and the variation of the refractive index depends both on the local exposure intensity (nonlinear effect) and on the amount of energy absorbed by the material (photosensitivity effect).

A light source for emitting said writing wave is for example, in the case of nonlinear photosensitivity, a pulsed source emitting pulses with a sufficient energy per pulse to trigger multiphoton absorption phenomena; the pulses have for example a pulse duration of less than 100 ns, advantageously less than 10 ns, and a luminous intensity of more than a few MW/cm², advantageously more than 100 MW/cm².

According to one or more exemplary embodiments, the nonlinear photosensitivity spectral band lies between 300 nm and 2 μm.

According to one or more exemplary embodiments, the exposure of the 2D array to the writing wave comprises projection through a mask of given amplitude, for example a mask similar to that used in photolithography, for example a chromium mask.

According to one or more exemplary embodiments, the exposure of the 2D array to the writing wave comprises illuminating the array point-by-point, for example by using a scanning of a focused laser.

According to one or more exemplary embodiments, the exposure of the 2D array to the writing wave comprises using a spatial light modulator of the liquid-crystal array or micromirror type.

According to one or more exemplary embodiments, the intended phase profile is a multilevel phase profile, for example a binary phase profile, with 4 levels, 8 levels, or more generally 2^{N} levels, where N is an integer greater than or equal to 1.

According to one or more exemplary embodiments, the intended phase profile is configured to generate a least one of the following optical functions in the working spectral band: converging or diverging lens, beam converter, beam splitter, projected image, for example a reticle, a grid, or more generally any intensity distribution forming an image, for example in the far field.

According to one or more exemplary embodiments, the resonant dielectric elements are formed by blocks, for example parallelepipedal blocks with a rectangular or square cross section, or cylindrical blocks, for example with a circular or oval cross section.

According to one or more exemplary embodiments, at least one dimension of said resonant dielectric elements is sub-wavelength.

According to one or more exemplary embodiments, the optical metasurface is configured to operate in reflection.

According to one or more exemplary embodiments, the optical metasurface is configured to operate in transmission.

According to one or more exemplary embodiments, the method further comprises a step of monitoring in real time the local refractive index variations experienced by at least one region of the 2D array during said exposure. This step makes it possible to obviate a calibration step during the manufacture of said metasurface.

For example, the monitoring comprises illuminating at least one region of the 2D array with an electromagnetic wave having at least one wavelength in the working spectral band and observing the resulting optical function.

According to one or more exemplary embodiments, the optical metasurface thus obtained may be reconfigured for a new application.

According to a second aspect, the present description relates to an optical metasurface configured to generate a given phase profile in a given working spectral band, said metasurface being obtained with a manufacturing method according to any one of the exemplary embodiments of the method according to the first aspect.

The present description relates more generally to an optical metasurface configured to generate a given phase profile in a given working spectral band, said metasurface comprising:
a substrate;
a 2D array of nanostructures forming resonant dielectric elements, said nanostructures being formed in at least one photosensitive dielectric material deposited on said substrate; and wherein:
said nanostructures are arranged in the form of identical patterns repeated periodically along two directions, with a sub-wavelength period along each direction, each pattern having a given refractive index variation with respect to a reference refractive index, so that each pattern of the 2D array produces, on an incident electromagnetic wave having a wavelength in the working spectral band, a phase variation corresponding to said refractive index variation.

According to one or more exemplary embodiments, said nanostructures are formed by parallelepipedal or cylindrical blocks.

The term “identical patterns” is intended to mean patterns of nanostructures which comprise the same arrangement of nanostructures, with the same shapes and the same dimensions for the nanostructures from one pattern to another.

According to a third aspect, the present description relates to a system for manufacturing an optical metasurface for carrying out the method according to the first aspect, the system comprising:
a support capable of receiving said 2D array of patterns, each comprising one or more nano structures;
an emission source of an electromagnetic wave, having at least one wavelength in said photosensitivity spectral band of said at least one photosensitive dielectric material;
a writing device placed between the emission source and the support and configured to modulate the amplitude and/or the phase of the electromagnetic wave in order to form said writing wave having the spatial energy distribution in the plane of the 2D array that is a function of said intended phase profile.

According to one or more exemplary embodiments, said writing device comprises a spatial electromagnetic wave modulator and a controller of said spatial electromagnetic wave modulator. For example, said spatial electromagnetic wave modulator comprises a liquid-crystal array or an array of micromirrors.

According to one or more exemplary embodiments, said writing device comprises a device for scanning a writing beam in two directions, in order to illuminate the 2D array point-by-point.

According to one or more exemplary embodiments, said writing device comprises an amplitude mask.

According to one or more exemplary embodiments, the system for manufacturing an optical metasurface further comprises an optical imaging system configured to monitor in real time the method for manufacturing the optical metasurface.

According to one or more exemplary embodiments, said optical imaging system is configured to measure the phase variation induced on a calibration region previously defined on the metasurface.

### BRIEF DESCRIPTION OF THE FIGURES

Other advantages and characteristics of the invention will become apparent on reading the description, which is illustrated by the following figures:

FIG. 1 represents a diagram illustrating an example of a method for manufacturing an optical metasurface according to the present description;

FIG. 2 represents a diagram illustrating an example of an optical metasurface according to the present description;

FIG. 3 represents a diagram illustrating an example of a system for manufacturing an optical metasurface according to the present description;

FIG. 4A represents a curve showing the transmission coefficient, calculated at normal incidence, for a 2D array of a metasurface according to an example of the present description;

FIG. 4B represents curves showing the transmission coefficient, calculated at normal incidence, for a 2D array of a metasurface according to an example of the present description, for different heights of the resonant dielectric elements;

FIG. 4C represents curves showing on the one hand the transmission coefficient and on the other hand the phase change variation, which are calculated at normal incidence, for a 2D array of a metasurface according to an example of the present description, for different exposure times;

FIG. 5A represents images illustrating a first example of a phase profile, which is binary, and a corresponding spatial intensity distribution in the far field;

FIG. 5B represents images illustrating a second example of a phase profile, with 4 levels, and a corresponding spatial intensity distribution in the far field.

### DETAILED DESCRIPTION OF THE INVENTION

In the following detailed description, only some exemplary embodiments are described in detail in order to ensure clarity of the explanation, although these examples are not intended to limit the general scope of the principles emerging from the present description.

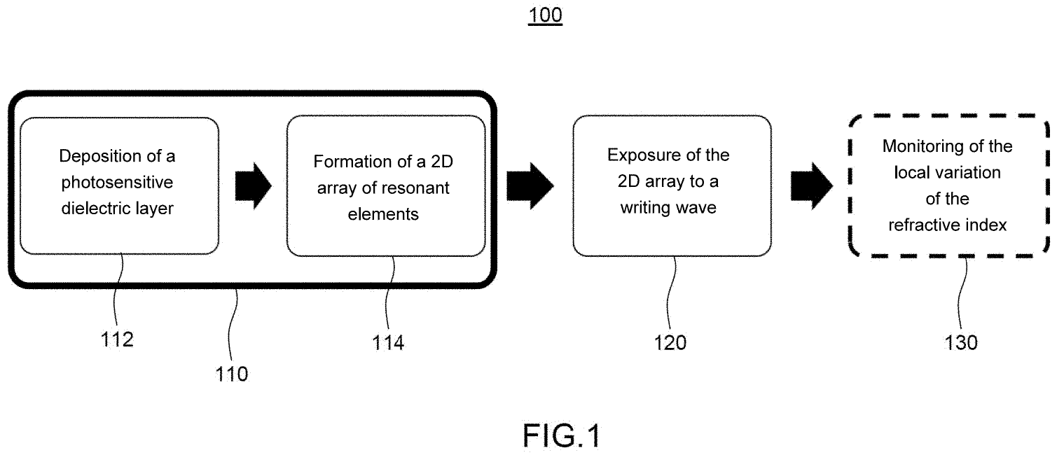

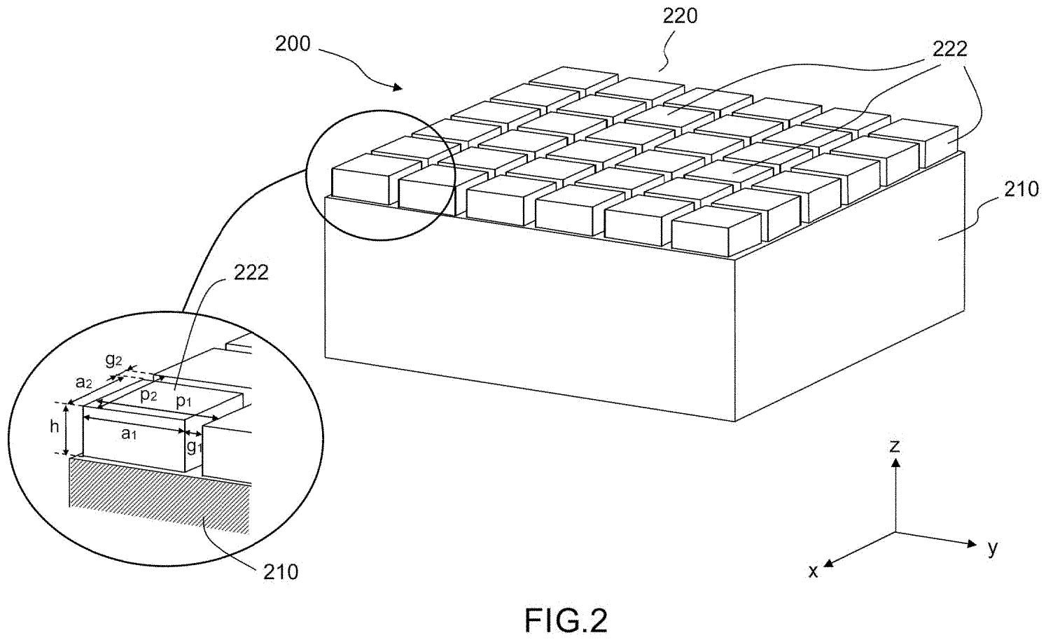

FIG. 1 represents a diagram illustrating an example of a method 100 for manufacturing an optical metasurface according to the present description, and FIG. 2 illustrates an example of an optical metasurface 200 according to the present description.

The example illustrated in FIG. 1 of a method 100 for manufacturing an optical metasurface comprises a step 110 of obtaining a 2D array of nanostructures forming dielectric elements that are resonant in a given working spectral band, then exposing 120 the 2D array obtained in this way to a writing wave.

According to one example, step 110 comprises depositing 112 a layer of dielectric material that is photosensitive in a given photosensitivity spectral band on a substrate 210 (FIG. 2), said photosensitive material being deposited in the form of a thin film, for example. The deposition may be carried out by physical methods such as evaporation or sputtering, or by chemical methods such as PE-CVD (plasma-enhanced chemical vapor deposition). In the case of polymers, methods of spin coating or dip coating may also be envisioned.

The photosensitive dielectric material exhibits refractive index change properties when it is exposed to a given electromagnetic wave, referred to as the writing wave in the present application. Typically, dielectric materials whose refractive index can vary by a given minimum amount, for example from 2% to 3% of the nominal value of the refractive index, are sought. Various dielectric materials may be envisioned for this purpose. They may for example be materials with linear photosensitivity that are inorganic, such as chalcogenide glasses (e.g. Ge₃₃As₁₂Se₅₅ (germanium-arsenic-selenium), As₂S₃ (arsenic trisulfide), etc.) or organic, such as phenanthrenequinone-doped poly(methyl methacrylate) (PQ:PMMA). It is also possible to use the nonlinear photosensitivity of materials exposed to ultrashort pulses, typically less than 1 ps. Mention may for example be made of silica (SiO2), see D. Homoelle et al., “Infrared photosensitivity in silica glasses exposed to femtosecond laser pulses,” Opt. Lett. 24, 1311-1313 (1999), niobia (Nb₂O₅).

The substrate is for example an organic material (PMMA etc.) or an inorganic material (silica, chalcogenide etc.) that is compatible with the material deposited as a thin film deposited on the surface (adhesion) or is itself photosensitive, if it is used as a support for the production of the surface grating.

The photosensitive material may be used either on its own or in combination with other thin-film materials. For example, mention may be made of the use of connecting layers (chromium, magnesium oxide (MgO) etc.) in order to make the substrate and the layer compatible, the use of multilayer structures on or under the photosensitive layer in order to limit losses by reflection at the interfaces (antireflection structures) and/or to increase the resonance phenomena and/or to increase the working interval of the metasurface (achromatic).

Step 110 then comprises forming 114 a 2D array of resonant dielectric elements in the layer of dielectric material.

In other exemplary embodiments, the obtaining 110 of the 2D array may comprise depositing the photosensitive dielectric material on a substrate through a mask, for example a resin mask, in order to form the resonant dielectric elements.

According to another exemplary embodiment, the resonant dielectric elements may be formed directly in a solid substrate itself made of photosensitive dielectric material. In the example of FIG. 2, the 2D array of resonant elements is referenced 220. The resonant dielectric elements 222 are arranged in the form of patterns organized periodically along two perpendicular directions (x, y). In this example, each pattern comprises a single resonant dielectric element 222. Each resonant dielectric element in this example has the shape of a block with a rectangular cross section, side lengths a₁, a₂ and height h. Two adjacent blocks are separated along each direction respectively by a distance p₁, p₂, so that the period along each direction is equal to p₁=a₁+g₁ and p₂=a₂+g₂, where p₁, p₂ are sub-wavelength.

Other shapes, organizations and dimensions are of course possible for the resonant dielectric elements 222 illustrated in FIG. 2. In particular, FIG. 2 shows elements 222 of parallelepipedal shape. Nevertheless, the elements 222 may have other shapes, for example cylindrical blocks with a round, oval cross section, etc. Further, in the example of FIG. 2 the dielectric element 222 is equivalent to a pattern. It is, however, possible to have a plurality of resonant dielectric elements with different shapes and/or dimensions within a pattern. In some exemplary embodiments, a pattern that is identical in terms of number, shapes and dimensions of said resonant dielectric elements is reproduced with a given sub-wavelength period in the two directions of the array, for example but not necessarily an identical period.

The exposure step 120 makes it possible to introduce local variations of the refractive index at a pattern level, and thus to control the transmitted phase.

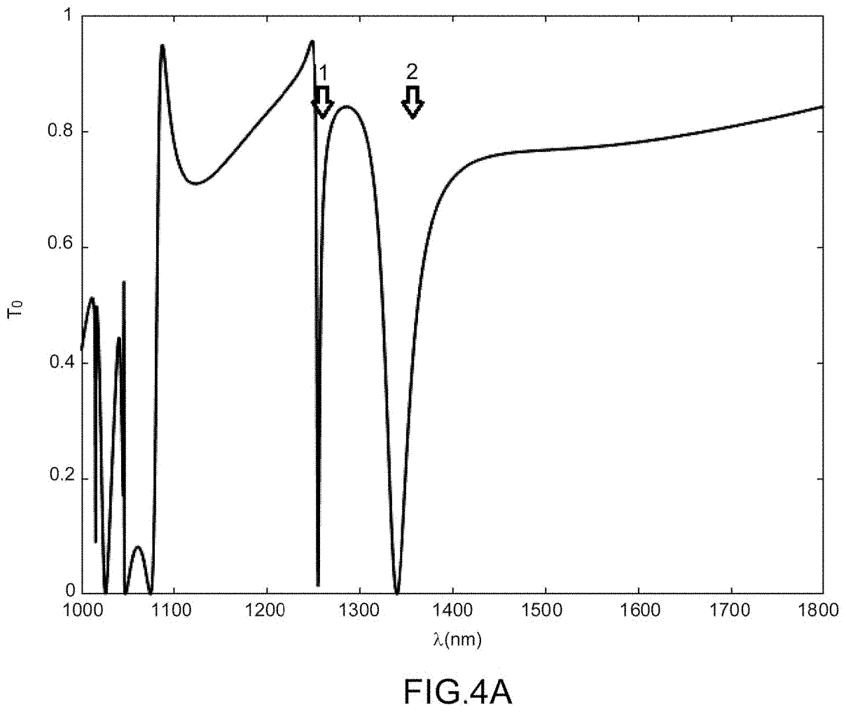

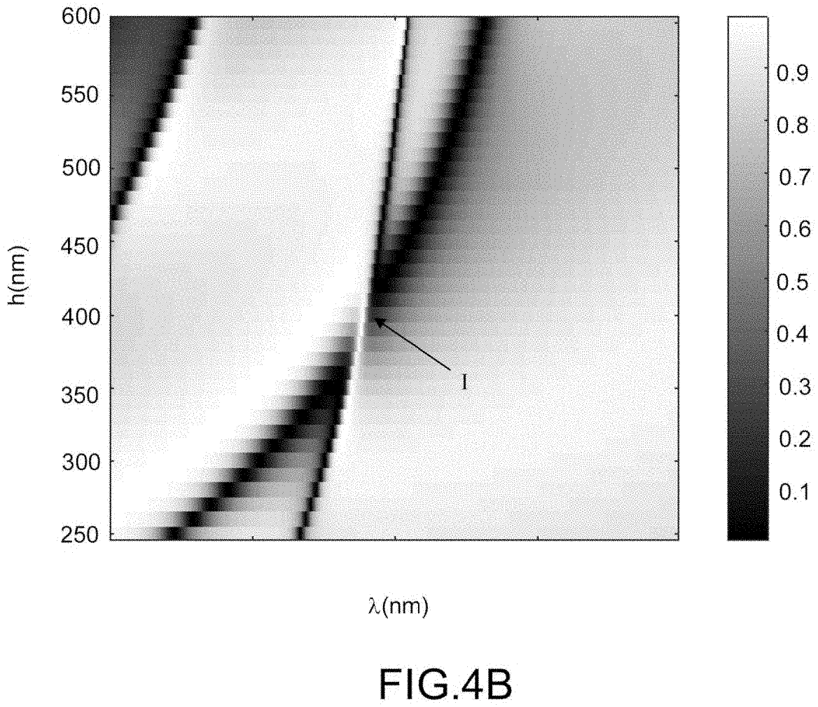

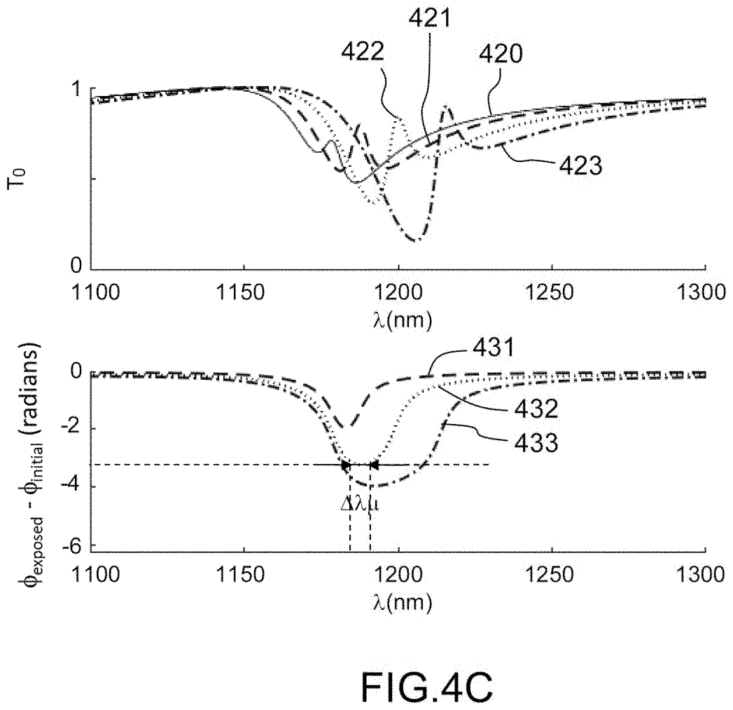

In general, the design of the 2D array (shape and dimensions of the resonant elements, organization in the form of patterns, period, etc.) depends on the working wavelength (or spectral range) and on the intended phase variation. Design methods will be described in more detail below with reference to FIGS. 4A-4C.

One known method for forming the 2D array of resonant elements in the layer of dielectric material comprises, for example, a step of electron-beam lithography in order to form the patterns of intended nanometric size in a resin then transfer of the patterns into the layer of dielectric material by ion etching. Another method comprises generating the resonant elements by nanoprinting. More precisely, a mold is used for replication of the basic pattern over a large surface. It is useful to note that the same basic pattern may be used regardless of the intended phase profile of the optical metasurface that is meant to be manufactured, since the local phase variation will be controlled by the distribution of the photoinduced index variations.

Once the 2D array of resonant elements has been obtained, the step 120 of exposing the 2D array to a writing wave makes it possible to create the intended phase profile for generating the desired optical function (for example, array of dots, reticle, vortex, projected image etc.). The intended phase profile is similar to that which is generally calculated for generating diffractive optical elements or holograms that are generated digitally, as described for example in the work by Bernard Kress, Patrick Meyrueis, “Applied digital optics”, Chapter 6 “Digital Diffractive Optics: Numeric Type”, John Wiley & Sons, 2009. The phase profile is a multilevel profile, for example one that is binary or that has a higher number of levels, typically 2^{N}.

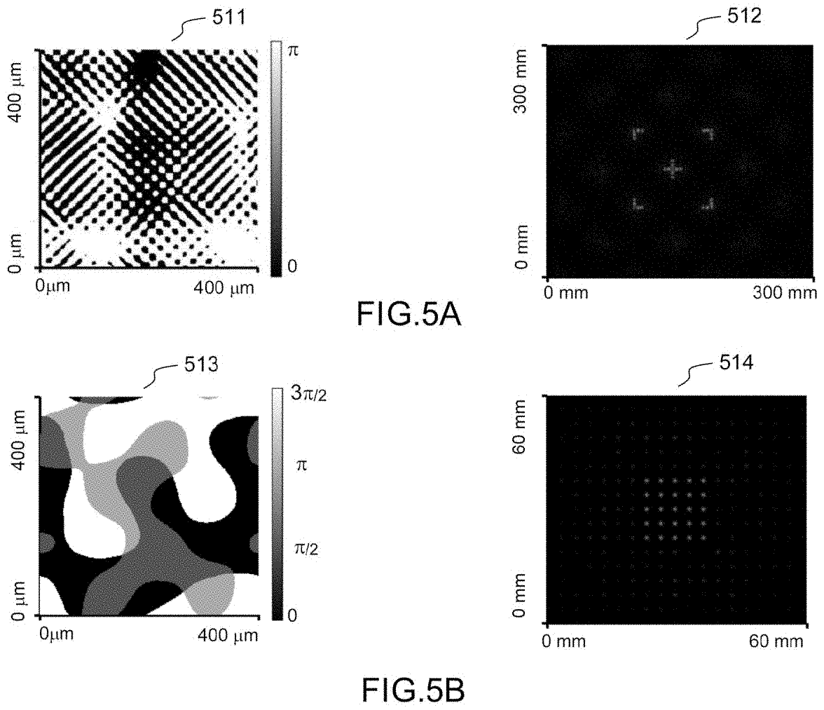

Examples of phase profiles and corresponding optical functions will be described with reference to FIG. 5.

The exposure of the 2D array comprises spatially and/or temporally selective exposure in order to obtain a photoinduced local variation of the refractive index.

The exposure duration may, for example, be a function of the refractive index variation to be photoinduced in order to produce a given phase variation. It will therefore be given by the calculated grating type structure (phase variation/index variation relation) and the photosensitivity properties of the material. In the case of linear photosensitivity, the exposure duration may be a function of the energy density of the exposure, while in the case of nonlinear photosensitivity the duration exposure may be a function of energy density of the exposure and of the intensity of the exposure beam, as explained in L. Siiman et al., “Nonlinear photosensitivity of photo-thermo-refractive glass by high intensity laser irradiation”, Journal of Non-Crystalline Solids, 354, 4070-4074 (2008) in the case of a photo-thermo-refractive glass.

For example, controlling the exposure dosage makes it possible to generate different levels of refractive index variations, which will make it possible to generate discrete values of phase variations on a light wave with a wavelength lying in the working spectral band. The selective exposure may for example be carried out by means of a spatial light modulator, as will be described in more detail below.

In the optical metasurface obtained in this way, the modulation of the refractive index variation in order to form the desired phase profile in the working spectral band is carried out a posteriori, which limits the errors in production of the basic dielectric structures.

Further, the method 100 for manufacturing an optical metasurface may optionally comprise in-situ optical monitoring 130, that is to say monitoring of the local variation of the refractive index, which makes it possible to control the process of manufacturing the optical metasurface in real time and thus to eliminate the calibration steps necessary for manufacture.

In this case, a laser emitting in the working spectral band of the metasurface illuminates the metasurface during manufacture. A camera may be placed downstream of the metasurface, optionally in combination with a lens, in order to measure the intensity profile transmitted by the metasurface in the far field. The exposure is terminated when the intensity profile obtained is identical to that calculated theoretically. This termination criterion may be defined as a merit function defining the mean deviation between the theoretical and experimental responses. Another method may consist in measuring the phase shift between the exposed zones and non-exposed zones, downstream of the metasurface, with the aid of an interferometer or a wavefront measuring system of the Shack-Hartmann type. The monitoring may be carried out in a given region of the optical metasurface.

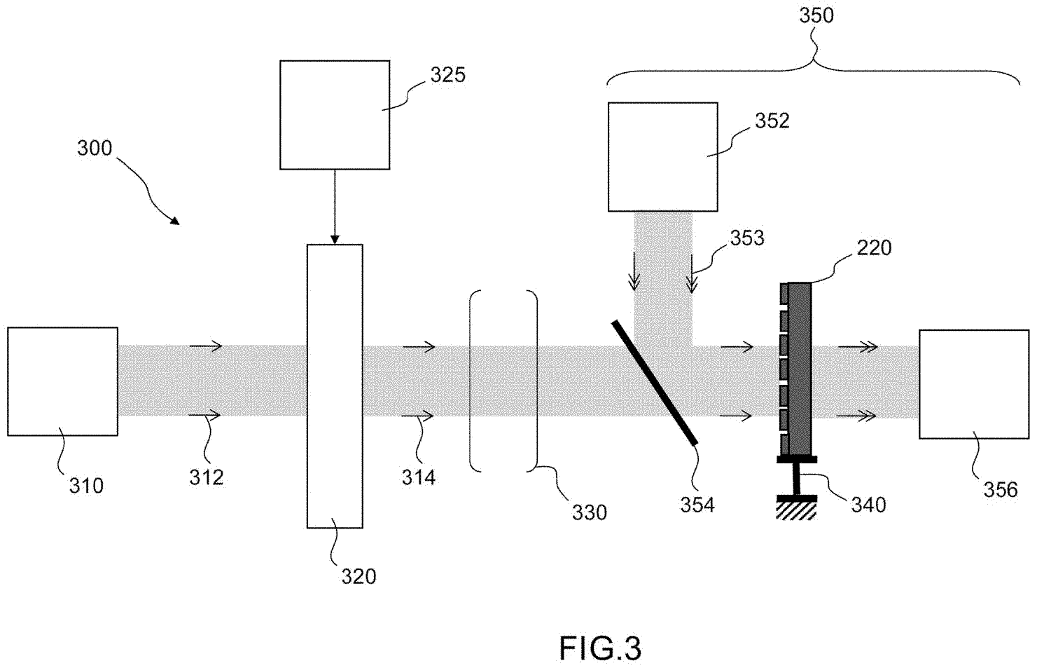

FIG. 3 schematically represents an example of a system 300 for manufacturing an optical metasurface, which is configured to carry out a manufacturing method according to the present description.

The manufacturing system 300 comprises a support 340 configured to receive a 2D array 220 of resonant dielectric elements 222. As explained above, the 2D array is designed to produce, after exposure to at least one writing electromagnetic wave, a phase variation on an incident electromagnetic wave having a wavelength in the working spectral band, according to an intended phase profile.

The manufacturing system 300 further comprises at least one emission source 310 of at least one electromagnetic wave 312 having at least one wavelength in the photosensitivity spectral band of the dielectric material(s) forming said resonant dielectric elements.

The emission source comprises for example a laser diode, a laser, a light-emitting diode, optionally fibered, and a system for shaping the beam, consisting of lenses or mirrors, in order to produce an exposure beam with a suitable size and intensity profile. The manufacturing system 300 also comprises a writing device 320 placed between the emission source 310 and the support 340 and configured to modulate the amplitude and/or the phase of the electromagnetic wave 312, and optionally a controller 325 configured to control said writing device 320 in order to produce a writing wave 314 that has the energy distribution that is a function of the index profile, and therefore of the intended phase profile, in the plane of the 2D array.

The writing device 320 may comprise a spatial light modulator, or SLM, configured to modulate the writing wave in amplitude in order to obtain the intended energy density. In the case of binary elements (0 and π), the intensity profile of the writing wave may be fixed during a given exposure time. In the case of writing phase profiles having more than 2 levels, the SLM may be reconfigured after each exposure corresponding to a phase level.

The writing device 320 may also comprise an array of micromirrors, each micromirror being configured to be tilted during a given exposure time by the controller in order to form the intended spatial energy distribution.

The writing device 320 may also comprise a system for scanning the 2D array point-by-point. In this case, the writing beam will be focused on the metasurface to be written with a spot diameter adapted to the size of the zones to be written, that is to say equal to or smaller than the smallest zone. The zone is to be understood here as a region intended to produce a uniform phase variation, for example 0 or π in the case of a binary phase profile. The metasurface will be kept fixed and the spot will then be scanned over the surface, for example with the aid of galvanometric mirrors, and the exposure duration of each point will be adapted as a function of the expected phase variation. Another option may consist in keeping the writing beam fixed and scanning the specimen.

The writing device 320 may also comprise a fixed-amplitude mask, of the chromium mask type similar to those used in photolithography.

In the example illustrated in FIG. 3, the manufacturing system 300 also comprises a relay optical system 330, comprising for example one or more objectives or lenses, which is configured to project the writing wave onto the 2D array. For example, the relay optical system 330 comprises an optical system of given magnification.

The controller 325 is configured to control the writing device 320 according to the intensity profile intended for the writing wave. The controller comprises, for example, a computer implemented for executing instructions. These instructions may be stored on any storage medium that can be read by the controller.

In the example of FIG. 3, the manufacturing system further comprises an optical device 350 configured to monitor in real time the refractive index variations experienced by said patterns of said 2D array during the exposure. The optical monitoring device 350 comprises, for example, an illumination source 352 configured to emit a monitoring wave 352 having a wavelength in the working spectral band. The optical monitoring device 350 further comprises a detector 356, for example a two-dimensional detector, for example a CCD or CMOS camera, onto which the optical function formed by the optical metasurface undergoing manufacture may be imaged in real time.

FIGS. 4A to 4C represent curves that illustrate steps for the design of a 2D array of resonant dielectric elements with a view to manufacturing an optical metasurface according to the present description.

A first step in the design of a 2D array is the selection of one or more photosensitive dielectric material(s) for forming the resonant elements. Photosensitive dielectric materials with significant variations of the refractive index, typically up to 2% to 3% of the refractive index, when they are illuminated with light waves having spectral bands lying in the visible, near-infrared and mid-infrared wavelength ranges, will advantageously be selected.

When the photosensitive dielectric material(s) are deposited on a substrate, the material of the substrate will also be selected for its physicochemical compatibility with the photosensitive material(s), optionally its transparency in the working spectral band.

As explained above, the dielectric medium may comprise a plurality of dielectric materials, including the photosensitive dielectric material(s), optionally an antireflection treatment at the air/photosensitive dielectric material interface and/or a connecting layer at the substrate/photosensitive dielectric material interface.

A second step comprises selection of the nanostructures (shapes, dimensions, organization) for forming the resonant dielectric elements and modeling of the response in transmission and/or in reflection of the structure formed in this way, in order to identify the resonance wavelength intervals. Of course, the modeling will take into account the characteristics (refractive index, layer thickness) of all the materials forming the dielectric medium, in particular the substrate and the photosensitive dielectric material(s), as well as the additional dielectric materials (antireflection, interface). The modeling may be done with known commercial software, for example CST MICROWAVE STUDIO®, COMSOL Multiphysics®, ANSYS HFSS®.

The nanostructures are organized in the form of patterns arranged periodically along the two directions of the 2D array. Periods less than the minimum wavelength of the working wavelength interval desired for operating in transmission or in reflection at the zeroth order, and for avoiding energy losses in higher diffraction orders, will be selected.

FIG. 4A thus represents a curve showing the transmission coefficient as a function of the wavelength for a 2D array of rectangularly shaped elements which is deposited on a substrate, such as is represented for example in FIG. 2. More precisely, for the calculation of FIG. 4A, cubes with a dimension a=600 nm are organized periodically with a period equal to p=700 nm in each of the directions. The refractive index of the photosensitive dielectric material is n=2.35 and the refractive index of the substrate is n_{sub}=1.5. The 2D array is illuminated in normal incidence and the transmission coefficient of the light propagating at normal incidence is calculated.

As illustrated in FIG. 4A, the transmission curve shows two troughs numbered “1” and “2” in the zeroth order region, corresponding to the positions of the resonances of the elements. It is shown that the first resonance (1) is principally an electric dipolar resonance and the second resonance (2) is principally a magnetic dipolar resonance. FIG. 4A also illustrates the other physical effects resulting from the periodic nature of the structure. For wavelengths λ<p·n_{sub} (in this example 1050 nm), the transmitted light is distributed between a plurality of diffracted orders. The metasurface will consequently be designed to operate with working wavelengths longer than a given wavelength, in this example 1050 nm, so as to have only the zeroth order transmitted.

Studies have shown, see Gomez-Medina et al., “Electric and magnetic dipolar response of germanium nanospheres: interference effects, scattering anisotropy, and optical forces”, Journal of Nanophotonics, 5(1), 053512 (2011), that by varying the aspect ratio of the basic patterns (ratio between height h and lateral dimensions a), it is possible to offset the electric and magnetic dipolar resonances with respect to one another and to find the point where they spectrally coincide.

A third step then consists in determining, for nanostructures with given shapes, the height h at which the electric and magnetic resonances spectrally coincide.

By way of illustration, FIG. 4B shows the transmission calculated at the 0^{th} order for nanostructures having a square cross section with a side length equal to a=600 nm and a height h variable between 250 nm and 600 nm.

As can be seen in FIG. 4B, as the height h of the nanostructures decreases, the electric and magnetic dipolar resonances are shifted with different rates toward shorter wavelengths. At around h=330 nm, these two minima are superimposed around a point referenced I in FIG. 4B. Further, the point I corresponds to a local transmission maximum.

A fourth step consists in calculating, around the height h previously determined, the variation of the transmission as a function of the wavelength at the zeroth order for a basic pattern (in the example selected, a parallelepipedal block with a square cross section) in the case in which the material is not exposed (n=2.35) and in the case in which the material is exposed (n=2.42).

FIG. 4C illustrates (upper curves) the transmission coefficient T₀ measured at the zeroth order when the 2D array is not exposed (curve 420) and when the 2D array has been exposed to different energy densities, respectively 1 J/cm² (curve 421), 4 J/cm² (curve 422) and 20 J/cm² (curve 423).

FIG. 4C further illustrates (lower curves) the phase variations φ_{exposed}−φᵢₙᵢₜᵢₐₗ experienced by the light incident on a basic pattern at normal incidence, for the same energy densities. More precisely, curves 431, 432, 433 illustrate the phase variations φ_{exposed}−φᵢₙᵢₜᵢₐₗ experienced by an incident wave for the energy densities of respectively 1 J/cm² (curve 431), 4 J/cm² (curve 432) and 20 J/cm² (curve 433).

A maximum variation of the phase φ_{exposed}−φᵢₙᵢₜᵢₐₗ equal to ˜4 radians is observed. Further, this phase variation is associated with a transmission that can be kept above 50%, or close to the initial transmission. This variation is sufficient for designing a lossless binary optical element.

Thus, for example, considering the curve 433 which shows the phase variation obtained with an exposure of 4 J/cm², it is observed that in a wavelength interval Δλᵤ centered on about 1185 nm and with a width of about 10 nm, the phase variation is π+/−15% and the transmission remains around 50%. It is therefore possible to produce a binary phase profile in this working wavelength interval.

This approach may be extended to arbitrary phase shifts between 0 and 2π, the value of which is controlled by the refractive index of the material.

FIGS. 5A and 5B illustrate two examples of phase profiles to be recorded in the 2D array with the aid of photoinduced index variations in order to obtain optical metasurfaces according to the present description. The spatial intensity distributions calculated in the far field for each of the phase profiles are represented.

Thus, FIG. 5A illustrates a first phase profile 511 that is binary (phase variations between 0 and π), making it possible to produce a far-field image 512 in the shape of a reticle.

FIG. 5B illustrates a second phase profile 513 with 4 phase levels (0, η/2, π and 3π/2), making it possible to produce a far-field image 514 in the shape of an array with 5×5 points.

Although described using a certain number of exemplary embodiments, the method for manufacturing an optical metasurface and the device for carrying out said method comprises different variants, modifications and improvements which will be readily apparent to the person skilled in the art, given that these different variants, modifications and improvements form part of the scope of the invention as defined by the following claims.

1. A method for manufacturing an optical metasurface configured to operate in a given working spectral band, the method comprising the following steps:
obtaining a 2D array of patterns, each comprising one or more nanostructures forming dielectric elements that are resonant in said working spectral band, said nanostructures being formed in at least one photosensitive dielectric material, said at least one photosensitive dielectric material having a refractive index that can be varied by exposure to at least one writing electromagnetic wave having a wavelength lying in a photosensitivity spectral band;
exposing said 2D array to a writing electromagnetic wave having at least one wavelength in said photosensitivity spectral band, said writing wave having a spatial energy distribution in a plane of the 2D array that is a function of an intended phase profile, so that each pattern of the 2D array produces, following said exposure, on an incident electromagnetic wave having a wavelength in the working spectral band, a phase variation corresponding to a refractive index variation experienced by said pattern during said exposure.

2. The method for manufacturing an optical metasurface as claimed in claim 1, wherein the obtaining of the 2D array comprises depositing said at least one photosensitive dielectric material on a substrate and forming said nanostructures in said at least one photosensitive dielectric material.

3. The method for manufacturing an optical metasurface as claimed in claim 1, wherein the obtaining of the 2D array comprises forming said nanostructures in a substrate comprising said at least one photosensitive dielectric material.

4. The method for manufacturing an optical metasurface as claimed in claim 1, wherein said phase profile is multilevel.

5. The method for manufacturing an optical metasurface as claimed in claim 1, further comprising a step of monitoring in real time the refractive index variations experienced by the patterns of at least one region of the 2D array during said exposure.

6. The method for manufacturing an optical metasurface as claimed in claim 1, wherein said patterns are identical and arranged periodically along two directions, the period along each direction being sub wavelength.

7. An optical metasurface configured to operate in a given working spectral band, said metasurface comprising:
a substrate,
a 2D array of nanostructures forming resonant dielectric elements that are formed in at least one photosensitive dielectric material deposited on said substrate; and wherein
said nanostructures are arranged in the form of identical patterns repeated periodically on the substrate along two directions, with a sub wavelength period along each direction, each pattern having a given refractive index variation with respect to a reference refractive index, so that each pattern of the 2D array produces, on an incident electromagnetic wave having a wavelength in the working spectral band, a phase variation corresponding to said refractive index variation.

8. The optical metasurface as claimed in claim 7, wherein nanostructures are formed by parallelepipedal or cylindrical blocks.

9. A system for manufacturing an optical metasurface for carrying out the manufacturing method as claimed in claim 1, the system comprising:
a support capable of receiving said 2D array;
an emission source of an electromagnetic wave having at least one wavelength in said photosensitivity spectral band of said at least one photosensitive dielectric material;
a writing device placed between the emission source and the support and configured to modulate the amplitude and/or the phase of the electromagnetic wave in order to form said writing wave having the spatial energy distribution in the plane of the 2D array that is a function of said intended phase profile.

10. The manufacturing system as claimed in claim 9, wherein said writing device comprises a spatial electromagnetic wave modulator and a controller configured to control said spatial modulator.

11. The system as claimed in claim 9, further comprising an optical device configured to monitor in real time the refractive index variations experienced by said patterns of at least one region of said 2D array during said exposure.
